(19) United States
(12) Patent Application Publication
(10) Pub. No.: US 2025/0191980 A1
(43) Pub. Date: Jun. 12, 2025

(54) SUBSTRATE STAGE INSPECTION METHOD AND SEMICONDUCTOR DEVICE MANUFACTURING METHOD INCLUDING THE SAME

(71) Applicant: Samsung Electronics Co., Ltd., Suwon-si (KR)

(72) Inventors: Kwangkeun SONG, Suwon-si (KR); Dongsoo LEE, Suwon-si (KR); Hyungseuck LEE, Suwon-si (KR); Sangsoon LIM, Suwon-si (KR); Jinhyeok JO, Suwon-si (KR); Joohoon CHOI, Suwon-si (KR)

(73) Assignee: Samsung Electronics Co., Ltd., Suwon-si (KR)

(21) Appl. No.: 18/661,891

(22) Filed: May 13, 2024

(30) Foreign Application Priority Data
Dec. 12, 2023 (KR) 10-2023-0180092

(51) Int. Cl. H01L 21/66; G01B 21/22; G01N 19/08; H01L 23/00

(52) U.S. Cl. CPC H01L 22/20; G01B 21/22; G01N 19/08; H01L 24/81; H01L 2224/81908

(57) ABSTRACT

Provided are a substrate stage inspection method and/or a semiconductor device manufacturing method using the same, in which a particle on a substrate stage is more accurately detected and tilt abnormality of the substrate stage is inspected. The substrate stage inspection method includes receiving data from a database (DB), calculating a tilt of a substrate stage by using the data, adjusting the data such that an effect of the tilt is reduced, detecting a particle on the substrate stage based on the adjusted data, and inspecting tilt abnormality of the substrate stage.

### CROSS-REFERENCE TO RELATED APPLICATION

This application is based on and claims priority under 35 U.S.C. § 119 to Korean Patent Application No. 10-2023-0180092, filed on Dec. 12, 2023, in the Korean Intellectual Property Office, the disclosure of which is incorporated by reference herein in its entirety.

### BACKGROUND

Various example embodiments relate to a substrate stage inspection method, and more particularly, to a method of inspecting particle presence and/or tilt abnormality of a substrate stage.

Semiconductor devices may be formed when a series of semiconductor processes are repeatedly performed on a silicon wafer substrate. A semiconductor substrate, e.g., a wafer on which the semiconductor devices are formed, may be individualized into a plurality of chips through a dicing process and/or a singulation process. The individualized chips may be mounted on a substrate, such as a lead frame, a printed circuit board (PCB), or (another) semiconductor wafer, through a die attach process. The die attach process may include a chip pickup process and a bonding process. The chip pickup process may denote a process of picking up and separating a chip of a diced wafer from an adhesive film by using a chip separation device. The bonding process may denote a process of attaching the picked up chip to a substrate such as a PCB.

### SUMMARY

Various example embodiments may provide a substrate stage inspection method and/or a semiconductor device manufacturing method using the same, in which a particle on a substrate stage may be accurately detected and tilt abnormality of the substrate stage may be inspected, and in some cases may be corrected or improved upon.

Additional aspects will be set forth in part in the description which follows and, in part, will be apparent from the description, or may be learned by practice of the presented embodiments.

According to various example embodiments, there is provided a substrate stage inspection and control method including receiving data from a database (DB), calculating a tilt of a substrate stage by using the data, adjusting the data such that an effect of the tilt is reduced, detecting a particle on the substrate stage, based on the adjusted data, and inspecting tilt abnormality of the substrate stage.

Alternatively or additionally according to various example embodiments, there is a substrate stage inspection and control method including receiving data about a bonding process of bonding a semiconductor chip on a printed circuit board (PCB), calculating a plane equation for a substrate stage upon which the PCB is placed, by using at least three points of a work area of a first nozzle from among nozzles of a bond head, adjusting an initial touch height of a location to be corrected to a first touch height, by using the plane equation, determining whether a particle is present on the substrate stage by comparing the first touch height with a set first reference touch height, inspecting tilt abnormality of the substrate stage by using the work area of the first nozzle, and determining whether the calculating of the plane equation to the inspecting of the tilt abnormality has been performed for the all nozzles. In response to determining that the calculating of the plane equation to the inspecting of the tilt abnormality have has been performed for the all nozzles, the calculating of the plane equation to the inspecting of the tilt abnormality is repeated for a nozzle for which the calculating of the plane equation to the inspecting of the tilt abnormality are not performed.

Alternatively or additionally according to various example embodiments, there is provided a semiconductor device manufacturing method including inspecting a substrate stage, controlling the substrate stage according to a result of the inspecting, and performing a semiconductor process by arranging a substrate on the substrate stage. The inspecting of the substrate stage includes receiving data about the semiconductor process from a database (DB), calculating a tilt of the substrate stage by using the data, adjusting the data such that an effect of the tilt is reduced, detecting a particle on the substrate stage, based on the corrected data, and inspecting tilt abnormality of the substrate stage.

### BRIEF DESCRIPTION OF THE DRAWINGS

Various example embodiments will be more clearly understood from the following detailed description taken in conjunction with the accompanying drawings in which:

FIG. 1 is a flowchart of substrate stage inspection method according to some example embodiments;

FIGS. 2A to 2C are respectively a conceptual diagram and a graph, which shows changes in touch heights of nozzles of a bond head, and a table showing touch Z values of points of a printed circuit board (PCB), when a particle is present on a substrate stage during a flip-chip bonding process;

FIGS. 3A to 3C are conceptual diagrams for describing an issue in detecting of a particle on a substrate stage when the substrate stage is tilted and an issue in detecting of a particle on a substrate stage when there are no adjacent chips;

FIG. 4 is a flowchart showing in detail calculating of a tilt of a substrate stage in the substrate stage inspection method of FIG. 1;

FIGS. 5A to 5E are conceptual diagrams for describing the calculating of the tilt of the substrate stage of FIG. 4;

FIGS. 6A to 6D are graphs and a conceptual diagram for describing a result of accurately detecting a particle on a substrate stage through calculating of a tilt to detecting of a particle in the substrate stage inspection method of FIG. 1;

FIGS. 7A and 7B are respectively a graph and a photograph for describing a process of setting a first reference touch Z used in the detecting of the particle in the substrate stage inspection method of FIG. 1;

FIG. 8 is a flowchart showing in detail inspecting of tilt abnormality of a substrate stage in the substrate stage inspection method of FIG. 1;

FIG. 9 is a conceptual diagram for describing the inspecting of the tilt abnormality of the substrate stage of FIG. 8;

FIGS. 10A and 10B are tables showing touch Z values of points of a PCB, which are adjusted by detecting tilt abnormality of a substrate stage through the calculating of the tilt of the substrate stage to the inspecting of the tilt abnormality in the substrate stage inspection method of FIG. 1;

FIG. 11 is a flowchart of a substrate stage inspection method together with a substrate stage control process, according to some example embodiments; and

FIG. 12 is a flowchart of a semiconductor device manufacturing method including a substrate stage inspection method, according to some example embodiments.

### DETAILED DESCRIPTION OF EXAMPLE EMBODIMENTS

Hereinafter, various example embodiments will be described in detail with reference to accompanying drawings. In the drawings, like reference numerals are used for like elements and redundant descriptions thereof will be omitted.

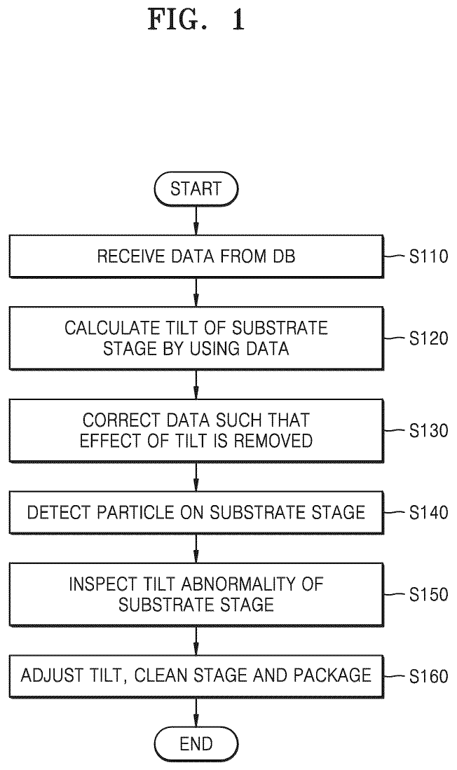

FIG. 1 is a flowchart of substrate stage inspection method according to some example embodiments.

Referring to FIG. 1, the substrate stage inspection method according to various example embodiments receives data from a database (DB), in operation S110. Here, the data may include data for a semiconductor process using a substrate stage. For example, in a case of a bonding process of bonding a semiconductor chip on a printed circuit board (PCB), the data may include information about one or more of mount equipment, a bond head, a nozzle, an encoder, and a PCB location.

Hereinafter, for convenience of description, a substrate stage inspection method for a flip-chip bonding process will be mainly described. However, the substrate stage inspection method of various example embodiments is not limited to the flip-chip bonding process. For example, the substrate stage inspection method of various example embodiments may be applied to any semiconductor process capable of obtaining, from the DB, coordinate information of points at three places (or, at least three places), and using a substrate stage 110. In detail, the substrate stage inspection method of various example embodiments may be applied to detecting a particle on a wafer stage or inspecting tilt abnormality of the wafer stage during a die attach process.

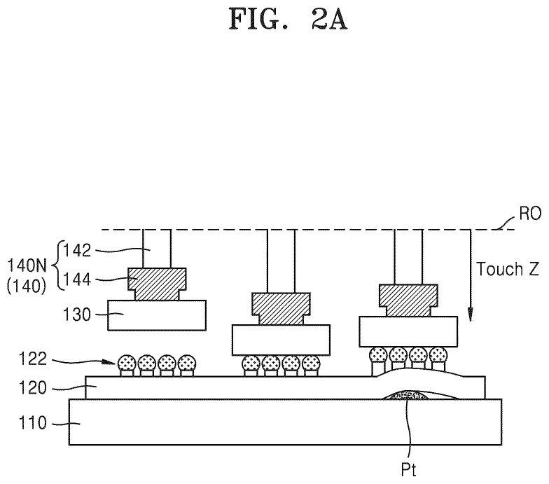

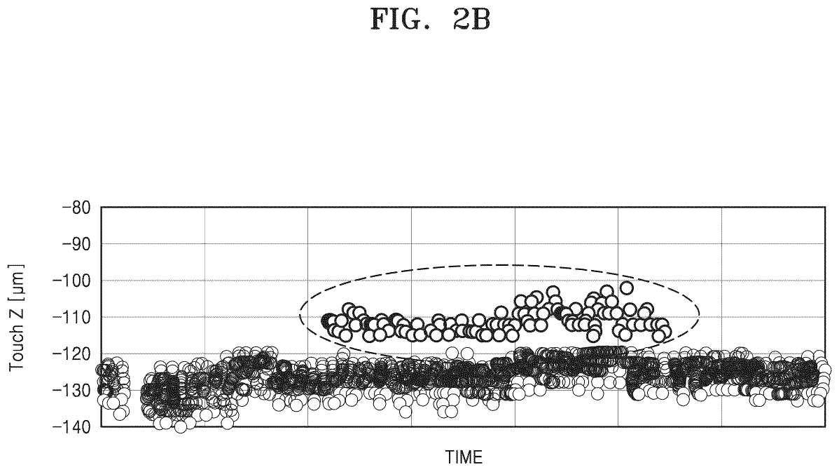

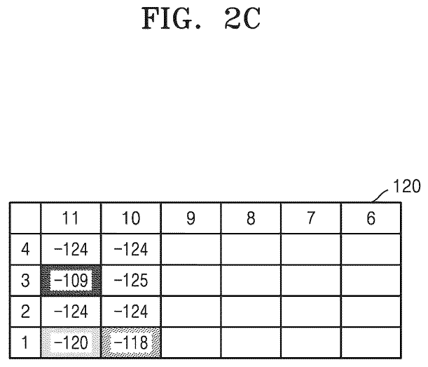

FIGS. 2A to 2C are respectively a conceptual diagram and a graph, which shows changes in touch heights of nozzles 140N of a bond head 140, and a table showing touch Z values of points of a PCB 120, when foreign material such as one or more particles Pt is present on the substrate stage 110 during a flip-chip bonding process.

Referring to FIGS. 2A to 2C, during the flip-chip bonding process, the PCB 120 may be disposed on the substrate stage 110. The bond head 140 may mount a semiconductor chip 130 on the PCB 120 by using a solder ball 122. For reference, the flip-chip bonding process may also be referred to as a flip-chip mount (FCM) process. The solder ball 122 may be disposed on a copper (Cu) pad of the PCB 120. Also, during the flip-chip bonding process, the solder ball 122 may be combined to a chip pad of the semiconductor chip 130.

As shown in FIG. 2A, bonding of the semiconductor chip 130 may be performed in a manner such that the solder ball 122 is arranged on the PCB 120 and the semiconductor chip 130 approaches and touches the solder ball 122 via the bond head 140. However, according to some example embodiments, the bonding may be performed in a manner such that the solder ball 122 is combined to the semiconductor chip 130, and the semiconductor chip 130 and the solder ball 122 together approach and touch the PCB 120 via the bond head 140.

The bond head 140 may vacuum-suck the semiconductor chip 130 and transfer the same during the flip-chip bonding process. In some example embodiments, the bond head 140 may make the semiconductor chip 130 approach and touch the PCB 120 such that the semiconductor chip 130 is mounted on the PCB 120. The bond head 140 may include the plurality of nozzles 140N therebelow. For example, the bond head 140 may include eight nozzles 140N. However, the number of nozzles 140N of the bond head 140 is not limited to eight, and may be more or less than eight.

Each of the nozzles 140N may include a base 142 and a suction pad 144. Each of the nozzles 140N may suck the semiconductor chip 130 through vacuum suction. Meanwhile, a work area on the PCB 120 may be set for each of the nozzles 140N. Accordingly, a bonding process for the semiconductor chip 130 in a specific work area may be performed by a corresponding nozzle 140N. In general, a plurality of work areas on the PCB 120, for example, two work areas, may be set for each of the nozzles 140N. However, according to some example embodiments, a single work area may be set for some nozzles 140N.

As shown in FIG. 2A, during the flip-chip bonding process, the nozzles 140N may move downward such that the sucked semiconductor chip 130 is combined to the solder ball 122 on the PCB 120. Here, a distance by which the nozzle 140N moved from a reference height R0 is referred to as a touch Z or a touch height. A touch Z value is measured by an encoder, and thus may be referred to as an encoder value.

Meanwhile, an impurity, such as the particle Pt may be adhered to and present on the substrate stage 110. When the particle Pt has a specific height, a height and shape of the PCB 120 may be changed by the particle Pt. Thus, when the particle Pt is present on the substrate stage 110, a phenomenon in which the nozzle 140N of a corresponding work area is lowered less, e.g., a phenomenon in which a touch Z value is decreased, may occur.

The graph of FIG. 2B shows the touch Z value for the nozzle 140N with respect to time, and the touch Z value is indicated in a negative (−) value downward, based on the reference height R0 as 0. For reference, (−) indicates a direction and may be ignored when comparing sizes of touch Z values.

In FIG. 2B, a work location of a section (a region surrounded by a broken line) where touch Z values are small may correspond to a location where the particle Pt is present. For example, in FIG. 2C, a touch Z value is indicated for each point of the PCB 120, and a touch Z value at a (11, 3) point is largely small compared to other points. Accordingly, it may be determined that the particle Pt is present at a location of the substrate stage 110, corresponding to the (11, 3) point of the PCB 120. In detail, a frame map of touch Z values may be prepared for the PCB 120, and when a phenomenon in which a touch Z value stands out in a work area of the specific nozzle 140N is found, the presence of the particle Pt on the corresponding substrate stage 110 may be deduced or determined and a location of the particle Pt may be detected. For reference, when the particle Pt is present on the substrate stage 110, a defect, such as a short circuit in which adjacent solder balls 122 are connected to each other or a chip fly in which the semiconductor chip 130 is detached from the PCB 120, may be generated.

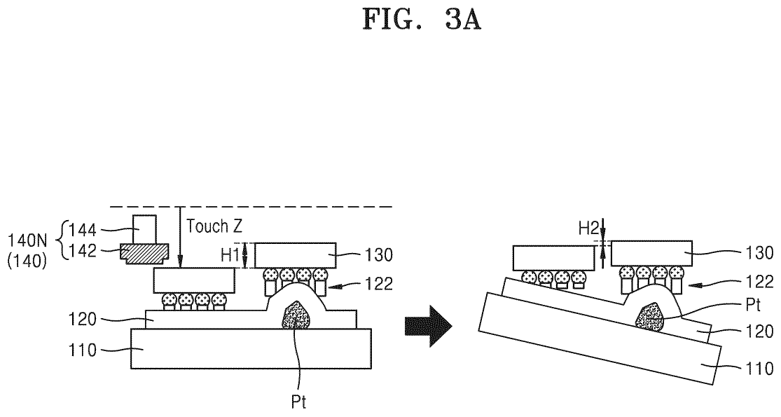

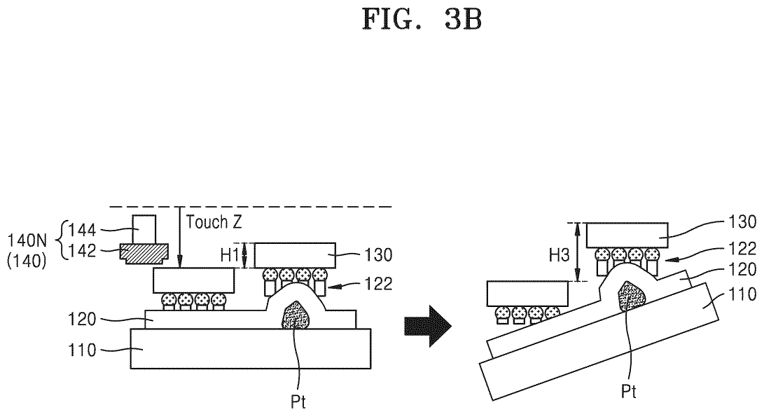

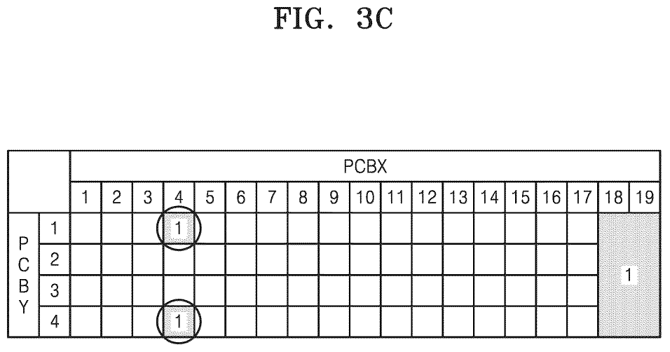

FIGS. 3A to 3C are conceptual diagrams for describing an issue in detecting of the particle Pt on the substrate stage 110 when the substrate stage 110 is tilted and an issue in detecting of the particle Pt on the substrate stage 110 when there are no adjacent chips.

Referring to FIG. 3A, when the substrate stage 110 maintains a horizontal state without a tilt as shown in the left drawing, the frame map of touch Z values for the PCB 120 may be prepared and the particle Pt on the substrate stage 110 may be detected as described above. For example, a difference between the touch Z values of the nozzles 140N at a location with the particle Pt and at a location without the particle Pt is indicated as a first height difference H1 equal to a height of the particle Pt, and such a first height difference H1 may be indicated on the frame map.

However, when the substrate stage 110 is tilted as shown in the right drawing, the difference between the touch Z values of the nozzles 140N at the location with the particle Pt and at the location without the particle Pt is indicated as a second height difference H2, which is obtained by subtracting a tilt from the first height difference H1, and such a second height difference H2 may be indicated on the frame map. The second height difference H2 is less than an actual height of the particle Pt, and thus, the particle Pt may not be detected. Also, the second height difference H2 does not reflect the accurate height of the particle Pt, and thus, consistency in data correction performed later may be reduced.

Referring to FIG. 3B, when the substrate stage 110 is tilted in a direction opposite to that shown in FIG. 3A, the difference between the touch Z values of the nozzles 140N at the location with the particle Pt and at the location without the particle Pt is indicated as a third height difference H3, which is obtained by adding a tilt to the first height difference H1, and such a third height difference H3 may be indicated on the frame map. However, the third height difference H3 is not the accurate height of the particle Pt, and thus, the consistency in the data correction performed later may also be reduced. Even when there is no particle Pt, the touch Z values of the nozzles 140N may differ, and thus, a false detection of determining that there is the particle Pt may occur.

A method of preparing the frame map of the touch Z values for the PCB 120 and detecting the particle Pt may be performed by comparing touch Z values of the bonding process for adjacent chips. However, when there is no adjacent chip immediately before a work and/or when a work order is not consistent, it may be difficult to detect the particle Pt because there is no target to be compared. For example, in FIG. 3C, when the flip-chip bonding process has been performed only at hatched points of the PCB 120 by a specific nozzle, for example, a first nozzle, there are no adjacent chips for circled points, and thus, a size or location of the particle Pt may not be detected.

For reference, a system for detecting and classifying a defect in a semiconductor process is referred to as a fault detection and classification (FDC) system, and the FDC system may monitor, in real time, data of facilities in a factory to detect, predict, and control an abnormal phenomenon. However, when a particle is unable to be detected as described above, a specification control of a flip-chip bonding process by the FDC system may become difficult.

However, the substrate stage inspection method of various example embodiments may prevent or reduce the likelihood of such issues by calculating a tilt of the substrate stage 110 and reflecting the tilt to data of a touch Z value, as will be described below. Accordingly, the substrate stage inspection method of various example embodiments may facilitate the specification control of the flip-chip bonding process by the FDC system.

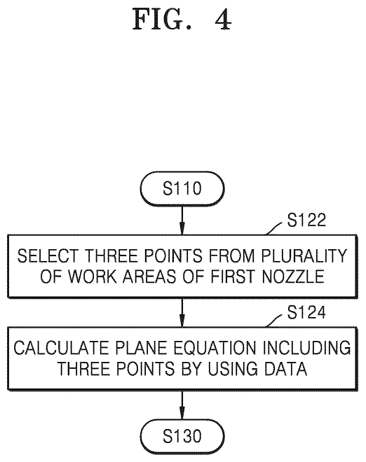

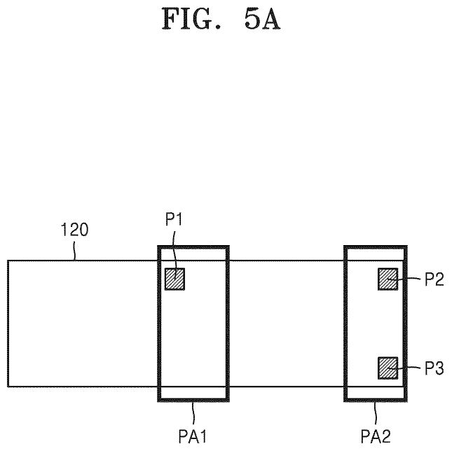

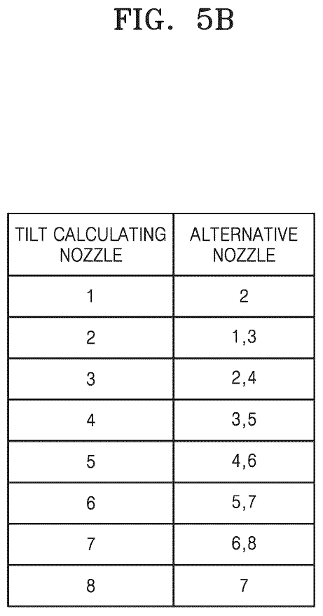

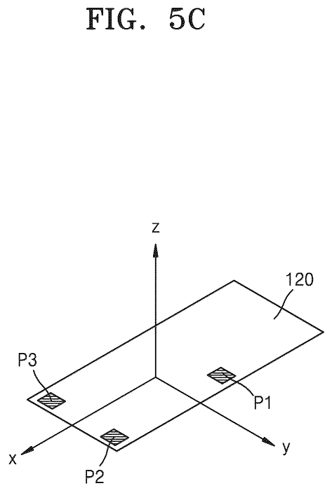

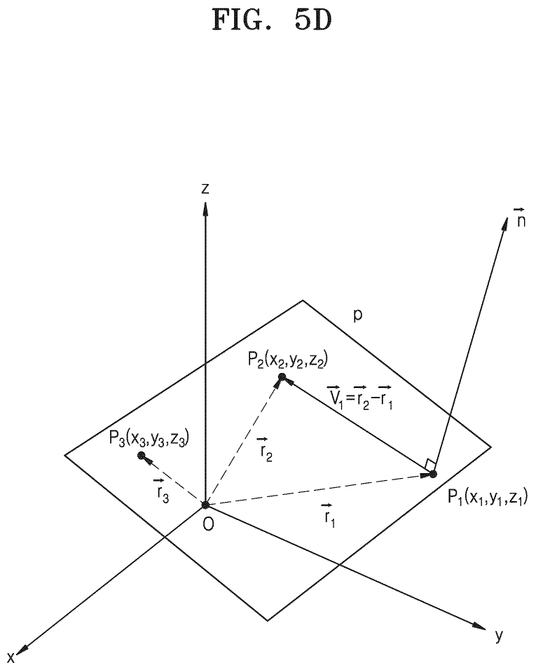

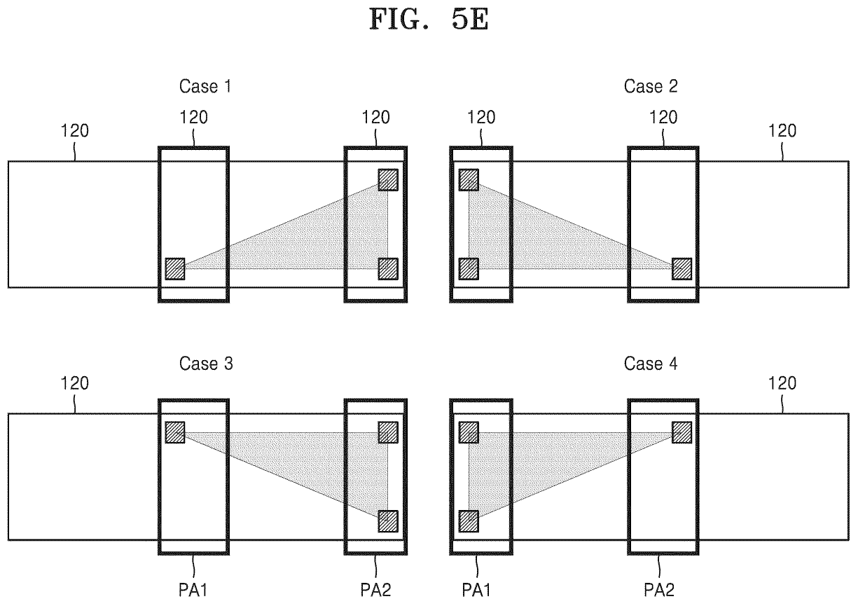

Referring back to FIG. 1, after the data is received, a tilt of the substrate stage 110 is calculated by using the data, in operation S120. The tilt of the substrate stage 110 may be calculated through a plane equation by using coordinate values of three points, or at least three points, in a work area of each of the nozzles 140N. In some example embodiments, the three points or the at least three points are choosen so as to not be collinear with one another. The plane equation may be calculated for all possible combinations of the three points of the work area per nozzle 140N. A specific method of calculating the tilt of the substrate stage 110 will be described in further detail with reference to FIGS. 4 to 5E.

After the tilt of the substrate stage 110 is calculated, the data is corrected such that an effect by the tilt is removed, in operation S130. Here, the data may denote, for example, a touch Z value at a corresponding point of the PCB 120. The correcting of the data may denote reflecting of the tilt of the substrate stage 110. In the substrate stage inspection method of various example embodiments, the data may be corrected by using the plane equation calculated above. When the plane equation has been calculated by using an alternative nozzle, the data may be corrected by reflecting an average touch Z value of the alternative nozzle. The correcting of the data will be described in further detail by using a specific plane equation below with reference to FIGS. 4 to 5E.

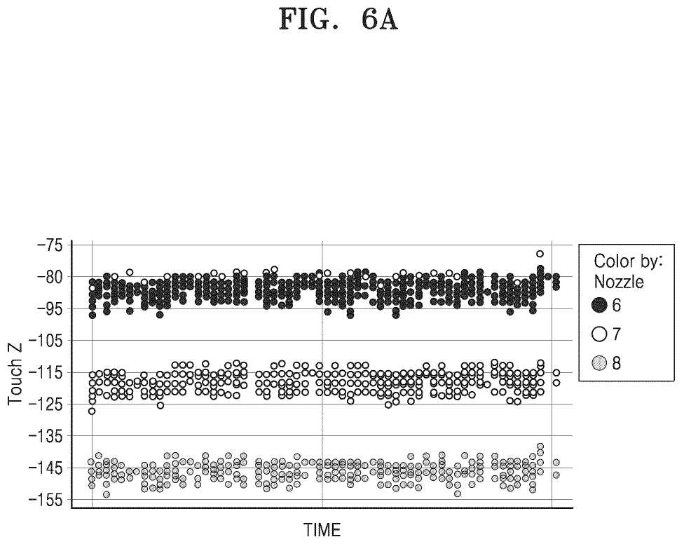

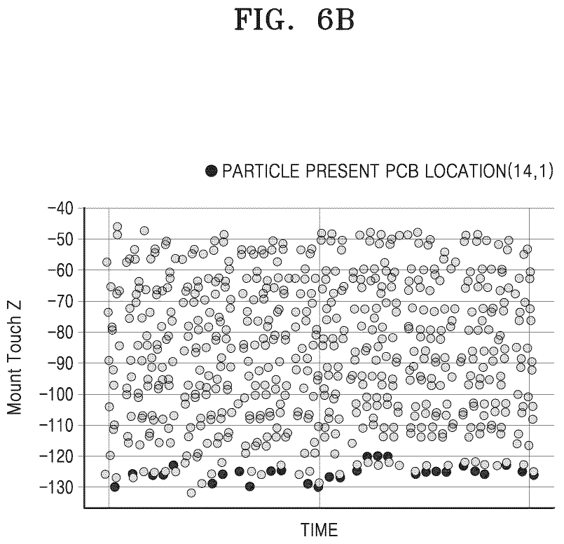

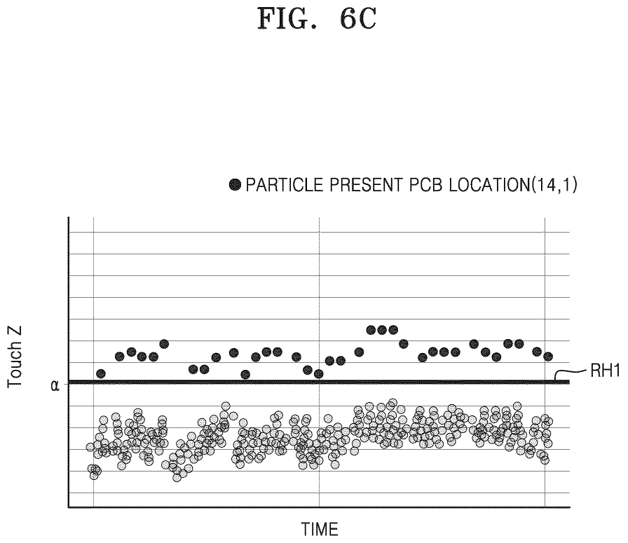

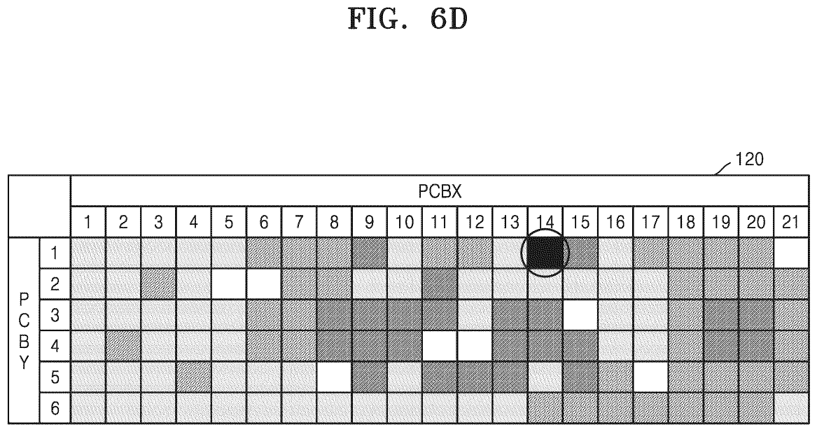

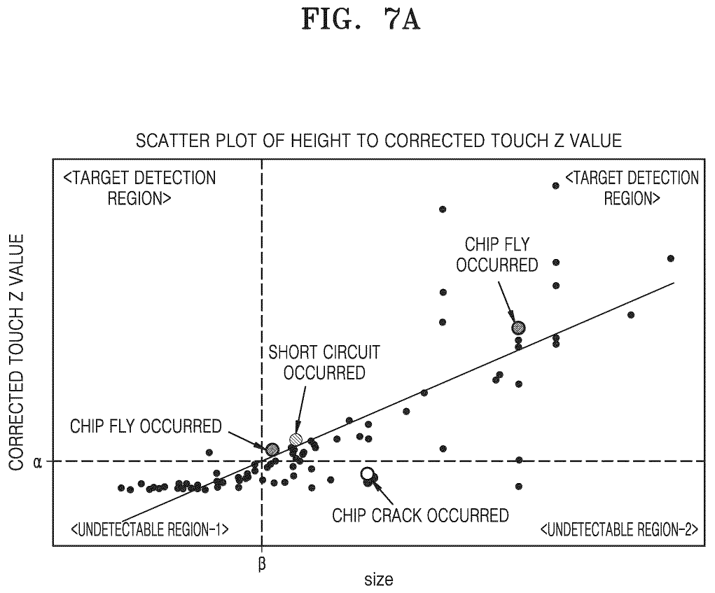

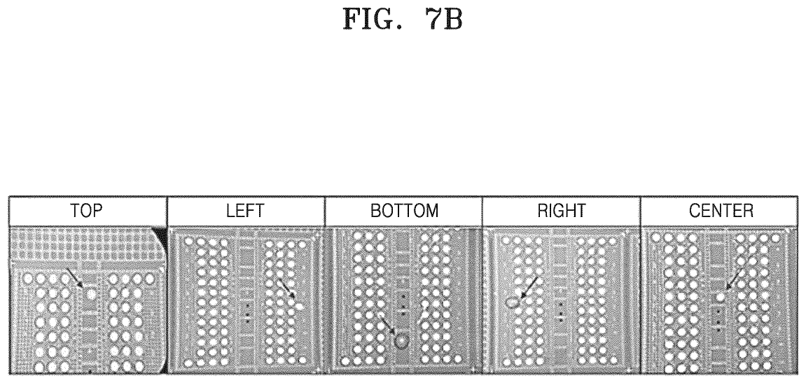

After the data is corrected, the particle Pt on the substrate stage 110 is detected based on the corrected data, in operation S140. The corrected data reflects the tilt of the substrate stage 110, and as a result, the particle Pt on the substrate stage 110 in a parallel state may be detected. However, the corrected data has a value obtained by subtracting a base touch Z value from the touch Z value, and thus, a corrected touch Z value in a region without the particle Pt may be 0. Accordingly, for a new PCB 120, a frame map of touch Z values may be prepared and the touch Z values may be compared with a set first reference touch Z RH1 of FIG. 6C to detect the particle Pt. For reference, the first reference touch Z RH1 may be set to a height where a bonding defect does not occur, by comparing and evaluating the bonding defect for each location and size of the particle Pt on the PCB 120. A method of detecting the particle Pt on the substrate stage 110, based on the corrected data, will be described in further detail with reference to FIGS. 6A to 7B.

After the particle Pt on the substrate stage 110 is detected in operation S140, tilt abnormality of the substrate stage 110 is inspected in operation S150. The tilt abnormality of the substrate stage 110 may be inspected by comparing a difference between, or may be based on a difference between, a maximum touch Z value and a minimum touch Z value at points of a work area for each nozzle with a second reference touch Z RH2. The second reference touch Z RH2 may be set based on one or more of a tilt management standard of the substrate stage 110, a thickness distribution of the semiconductor chip 130, a thickness distribution of the solder ball 122, a thickness distribution of the PCB 120, and an error distribution of a measurer.

When it is determined that there is the tilt abnormality in the substrate stage 110, a process of controlling the substrate stage 110 to adjust the tilt of the substrate stage 110 may be performed.

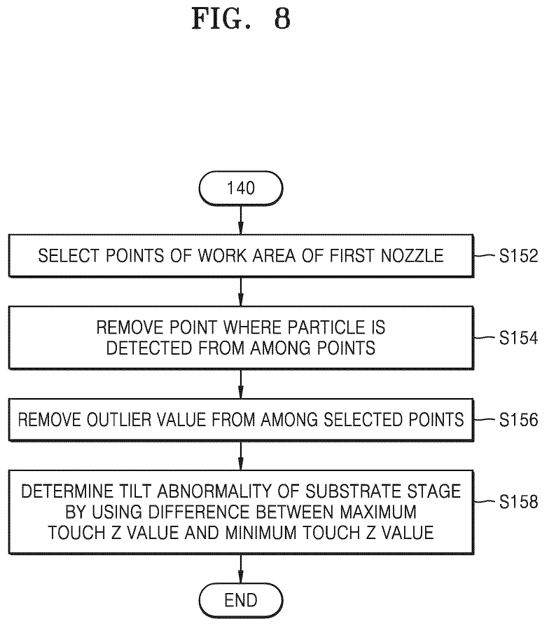

The tilt abnormality of the substrate stage 110 may be inspected for all nozzles 140N. For example, operation S120 to operation 150 may be repeated for the all nozzles 140N. The inspecting of the tilt abnormality of the substrate stage 110 will be described in further detail with reference to FIGS. 8 to 10B.

The substrate stage inspection method of various example embodiments may calculate the tilt of the substrate stage 110 by calculating the plane equation by using the data in the DB and reflect the tilt of the substrate stage 110 to the data, for example, data of a touch Z. Accordingly, the frame map of the touch Z for the PCB 120 may be prepared regardless of the tilt of the substrate stage 110 and the particle Pt on the substrate stage 110 may be accurately (or more accurately) detected. In some example embodiments, the tilt abnormality of the substrate stage 110 for each nozzle 140N may be accurately (or more accurately) inspected. As a result, the specification control of the FDC system may be facilitated based on the substrate stage inspection method of various example embodiments, and accordingly, a product yield may be greatly improved by stably performing the semiconductor process, e.g., the flip-chip bonding process.

FIG. 4 is a flowchart showing in detail the calculating of the tilt of the substrate stage 110 in the substrate stage inspection method of FIG. 1, and FIGS. 5A to 5E are conceptual diagrams for describing the calculating of the tilt of the substrate stage 110 of FIG. 4. Details that have been described above with reference to FIGS. 1 to 3C may be briefly described or omitted.

Referring to FIGS. 4 and 5A, in operation S120 of calculating the tilt of the substrate stage 110 in the substrate stage inspection method of various example embodiments, three or at least three points, e.g., first to third points P1 to P3, are selected from first and second work areas PA1 and PA2 of a first nozzle 140N that is one of the plurality of nozzles 140N of the bond head 140, in operation S122. For example, the first point P1 may be selected from the first work area PA1 and the second point P2 and third point P3 may be selected from the second work area PA2. As described above, a work area is set on the PCB 120 for each nozzle 140N, and generally, a plurality of, e.g., two, work areas may be set for each nozzle 140N. Alternatively or additionally, a plurality of points may be included in the work area. Here, the point may correspond to a location where the semiconductor chip 130 is mounted on the PCB 120. For example, as shown in FIG. 5A, the point may indicate a chip size and shape on the PCB 120. Also, to distinguish the points, the points may be indicated in x-axis and y-axis coordinates as shown in FIG. 2C or 3C.

The first point P1 to the third point P3 may be selected from at least two work areas. For example, the first point P1 to the third point P3 are not all selected from the first work area PA1 or from the second work area PA2. This may be because, when three points are all selected from a single area, consistency may decrease as an effect of tilt on distribution increases. Accordingly, when a work area of a specific nozzle is set to a single area, three points may be selected from a work area of an adjacent alternative nozzle instead of the specific nozzle. As shown in Table of FIG. 5B, from among tilt calculating nozzles on the left, three or at least three points may be selected from a work area of an adjacent nozzle for a nozzle having a single work area. For example, when a work area of a first nozzle is a single area, three points may be selected from a work area of a second nozzle adjacent to the first nozzle. Three points may be selected from a work area of any one nozzle from among adjacent two adjacent nozzles, except for the first nozzle and an eighth nozzle.

Referring to FIGS. 4, 5B, and 5C, after the first point P1 to the third point P3 are selected from the first work area PA1 and the second work area PA2, a plane equation including the first point P1 to the third point P3 is calculated by using the data, in operation S124. In detail, the PCB 120 is arranged on an x-y-z 3-dimensional coordinate axis as shown in FIG. 5C, and the plane equation including the first point P1 to the third point P3 is obtained by using the selected first point P1 to the third point P3 on the PCB 120. For reference, the PCB 120 may be curved due to presence of the particle Pt, and thus, it may be difficult to say that the plane equation accurately represent a top surface of the PCB 120. However, it may be assumed that the plane equation approximately represents the top surface of the PCB 120 in an area including the first point P1 to the third point P3. Also, it may be assumed that the plane equation represents a top surface of the substrate stage 110 in the area excluding a thickness of the PCB 120.

The plane equation including the first point P1 to the third point P3 may be calculated by using coordinates of the first point P1 to the third point P3 obtained from the data. FIG. 5D illustrates a plane including the first point P1 to the third point P3 and the coordinates of the first point P1 to the third point P3. For reference, an x-coordinate and a y-coordinate of each of the first point P1 to the third point P3 may be obtained from data about coordinates of the points on the PCB 120. Also, a z-coordinate may be obtained through a touch Z of the corresponding point.

According to a method of obtaining the plane equation, when a coordinate value of the first point P1 is (x₁, y₁, z₁), a coordinate value of the second point P2 is (x₂, y₂, z₂), and a coordinate value of the third point P3 is (x₃, y₃, z₃), vectors; and of the first point P1 to the third point P3 may contain the coordinate values as components. Also, \vec{V}₁=\vec{r₂}−\vec{r₁}=(x₂−x₁, y₂−y₁, z₂−z₁)=(V₁₁, V₁₂, V₁₃), and \vec{V₂}\vec{V₂}=(x₃−x₂, y₃−y₂, z₃−z₂)=(V₂₁, V₂₂, V₂₃).

Meanwhile, when the plane equation including the first point P1 to the third point P3 is ax+by +cz+d=0, a normal vector \vec{n} of a corresponding plane is indicated as (a, b, c), components of the normal vector \vec{n} may be calculated according to a=V₁₂*V₂₃−V₁₃*V₂₂, b=V₁₃*V₂₁−V₁₁*V₂₃, and c=V₁₁*V₂₂-V₁₂*V₂₁ by using components of \vec{V₁} and \vec{V₂}. Also, d may be calculated according to a*x₁+b*y₁+c*z₁+d=0 by substituting the coordinate value of the first point P1. Obviously, d may be calculated by substituting the coordinate value of the second point P2 or the third point P3.

Tilt distortion may occur when a particle is present at a selected point, and thus, the plane equation may be calculated by using all combinations of three points of a work area of a corresponding nozzle.

FIG. 5E illustrates cases where three points are selected from the first work area PA1 and the second work area PA2 of the first nozzle 140N in four combinations. For example, Case 3 may correspond to a selection of three points as shown in FIG. 5A. In FIG. 5E, the four combinations are illustrated under the assumption that two points are included in each of the first work area PA1 and the second work area PA2. However, in reality, three or more points may be included in one work area. Accordingly, the number of possible combinations of three points may be much greater than four.

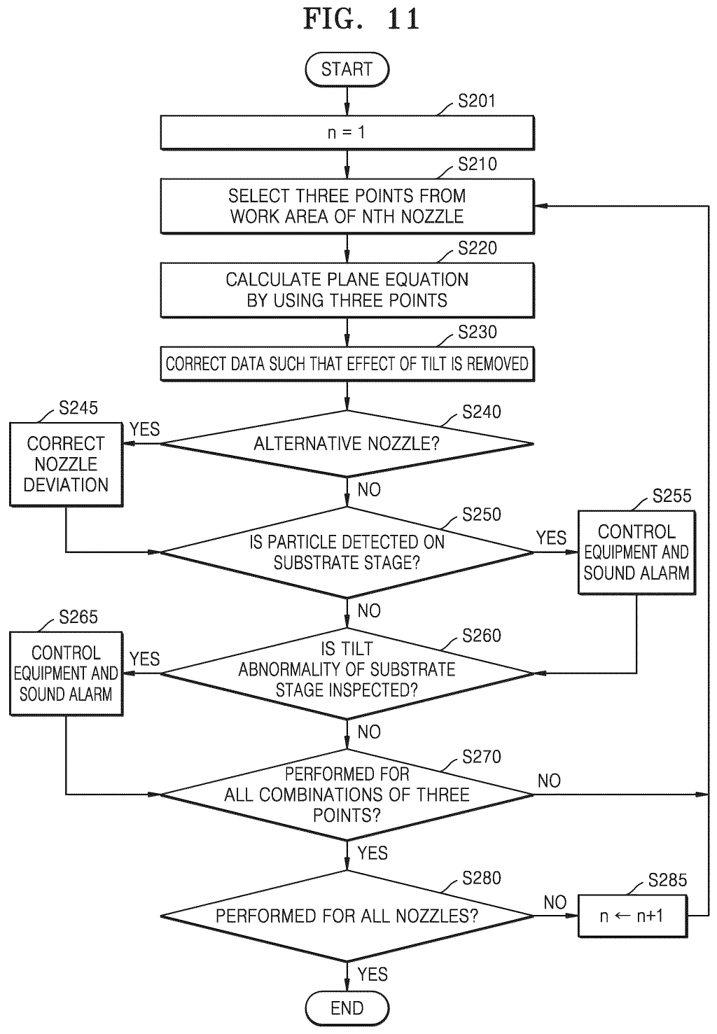

For reference, when three points are selected, one plane equation is calculated accordingly, and then data correction and particle detection may be performed by using the plane equation. Then, a new plane equation is calculated by using another combination of the three points, and the data correction and the particle detection are performed by using the new plane equation. A sequential flow related to a combination of selecting three points will be described in further detail with reference to FIG. 11.

When the plane equation is calculated, the effect of the tilt of the substrate stage 110 may be removed or improved upon by correcting or adjusting the data by using the plane equation, in operation S130. Further describing with reference to the plane equation of ax+by +cz+d=0 obtained above, when a touch Z value of the first point P1 is z₀ while the substrate stage 110 is in a horizontal state without being tilted and a touch Z value of the first point P1, obtained by removing the effect of the tilt of the substrate stage 110, is z_{con}, z_{con} may be calculated according to Equation 1 below.

$${z}_{con} = {z}_{0} - ( - d - {ax}_{0} - {by}_{0} ) / c \qquad [ Equation 1 ]$$

In Equation 1, a, b, and c are pre-calculated by using the components of the normal vector \vec{n}. Alternatively or additionally, when x₀ and y₀ are input to the plane equation except for z corresponding to the actual touch Z value at the first point P1, ax₀+by₀+cz+d=0, and when changed to an equation for z, z=(−d−ax₀−by₀)/c. Thus, z_{con} may be obtained by subtracting z from z₀. For reference, when the substrate stage 110 is in the horizontal state without being tilted, (−d−ax₀−by₀)/c matches z₀, and thus, z_{con} may be 0. Thus, a normal touch Z value after correction approaches 0.

When the data is corrected or adjusted by using a plane equation calculated using an alternative nozzle, the touch Z value of the first point P1 is subtracted by an average touch Z value of the alternative nozzle. Accordingly, when an actual touch Z value of the first point P1 from which the effect of the tilt of the substrate stage 110 is removed is z′_{con}, z′_{con} may be calculated according to Equation 2 below.

$${z}_{c o n}^{′} = {z}_{con} - Mean ( Touch Z ) \qquad [ Equation 2 ]$$

In Equation 2, z_{con} may correspond to the touch Z value of the first point P1 obtained by using the plane equation calculated with the alternative nozzle, and Mean (Touch Z) may correspond to the average touch Z value of the alternative nozzle. When calculating the average touch Z value of the alternative nozzle, outlier values may be removed to improve consistency. The average touch Z value may be based on one or more of a mean, a median, or a mode touch Z value and/or some other measure of central tendency; example embodiments are not limited thereto

Referring back to FIG. 1, in some example embodiments the method may further include operation S160, in which the substrate stage 110 is cleaned and the particle Pt is removed. In some example embodiments, the substrate stage 110 may be cleaned, e.g., with an air blowing process; however, example embodiments are not limited thereto. In some example embodiments, by cleaning the substrate stage 110 and removing the particle Pt, semiconductor devices may be packaged, e.g., packaged with a higher yield and with less of a chance of a short circuit.

FIGS. 6A to 6D are graphs and a conceptual diagram for describing a result of accurately detecting a particle on a substrate stage through the calculating of the tilt to the detecting of the particle in the substrate stage inspection method of FIG. 1. FIGS. 6A to 6D will be described with reference to FIGS. 1 and 4 to 5E together, and details that have been already described with reference to FIGS. 1 to 5E will be briefly described or omitted.

Referring to FIGS. 6A and 6B, FIG. 6A illustrates touch Z values of sixth, seventh, and eighth nozzles 140N when the particle Pt is present on the substrate stage 110 and the substrate stage 110 is in a horizontal state without being tilted. As shown in the graph of FIG. 6A, the sixth, seventh, and the eighth nozzles 140N have different offset values. For example, based on the different offset values, the sixth nozzle 140N may have the touch Z value of −90 on average, the seventh nozzle 140N may have the touch Z value of −120 on average, and the eighth nozzle 140N may have the touch Z value of −145 on average. Accordingly, it may be difficult to set a reference value for determining existence of the particle Pt due to a difference between the offset values of the nozzles 140N. As a result, in the graph of FIG. 6A, despite that the particle Pt is present in a work area of the seventh nozzle 140N, it may be difficult to detect the particle Pt because there is no difference between the touch Z values of the sixth nozzle 140N and the seventh nozzle 140N. Such an issue caused by the difference between the offset values does not occur only between the nozzles 140N of bonding equipment, and may be further between pieces of bonding equipment.

FIG. 6B illustrates the touch Z values of the first nozzle 140N when there is the particle Pt on the substrate stage 110 while the substrate stage 110 is tilted. The work area of the first nozzle 140N may include, for example, a (14, 1) point on the PCB 120. As shown in the graph of FIG. 6B, when the substrate stage 110 is tilted, the touch Z values of the first nozzle 140N may spread widely and be disordered. Accordingly, the particle Pt may not be detected even when the particle Pt is present on the substrate stage 110 corresponding to the (14, 1) point of the PCB 120, which is the work area of the first nozzle 140N.

Referring to FIGS. 6C and 6D, FIG. 6C illustrates the data corrected or adjusted by using the plane equation, e.g., corrected touch Z values, based on the substrate stage inspection method of various example embodiments. For example, when the work area of the first nozzle 140N includes the (14, 1) point of the PCB 120, it is identified that the corrected touch Z values at the (14, 1) point are greater than a that is a value of the first reference touch Z RH1. As described above, for the corrected touch Z values, a normal value without a particle is close to 0. As a result, in the substrate stage inspection method of various example embodiments, the normal values are made to be 0 through correction, and a reference value, for example, the value of the first reference touch Z RH1 is set to easily detect the particle Pt. Thus, the substrate stage inspection method of various example embodiments may be applied to an actual semiconductor system and facility including a substrate stage to more accurately and/or more easily detect a particle. The value a of the first reference touch Z RH1 will be described in further detail with reference to FIGS. 7A and 7B. Meanwhile, FIG. 6D illustrates a frame map of the PCB 120 including the corrected touch Z values, which are shown in shades of black and white instead of numerical values. For example, a corrected touch Z value may be high when a color thereof is close to dark black, and may be low when the color thereof is close to light white. The particle Pt may be detected at a location of the substrate stage 110, which corresponds to the (14, 1) point of the PCB 120, through the frame map of the PCB 120.

FIGS. 7A and 7B are respectively a graph and a photograph for describing a process of setting the first reference touch Z RH1 used in the detecting of the particle in the substrate stage inspection method of FIG. 1. In the graph of FIG. 7A, an x-axis denote a planar size of a particle and a y-axis denotes a corrected touch Z value. FIGS. 7A and 7B will be described with reference to FIGS. 1 and 6C together, and details that have been already described with reference to FIGS. 1 to 6D will be briefly described or omitted.

Referring to FIGS. 7A and 7B, the graph of FIG. 7A is obtained by evaluating a defect of the corrected touch Z value by producing a sample for each location and for each size of the particle Pt on the PCB 120. It is identified that a defect did not occur regardless of a size of the particle Pt below a broken line corresponding to a. Thus, a region below a horizontal broken line is classified as an undetectable region. Here, the defect includes only a short circuit defect and a chip fly defect, and excludes a chip crack.

For reference, the short circuit defect is identified when the particle Pt is located at a center of a chip, for example, at a rightmost center of FIG. 7B. The short circuit defect is analyzed to occur, for example, after a reflow process due to pressing of a solder bump during a bonding process. The chip fly defect is identified to occur when the particle Pt is located at an edge of the chip, for example, at the top, left, bottom, and right of FIG. 7B, from the left. The chip fly defect is analyzed to occur, for example, during a handling process of the PCB 120 before the reflow process.

As determined through a solid line with a slope in the graph of FIG. 7A, the corrected touch Z value may increase when a planar size of the particle Pt increases. Alternatively or additionally, a defect may be detected in a target detection region in which the planar size of the particle Pt is less than B, but is not detected during evaluation, and the defect may be detected only in a target detection region in which the planar size of the particle Pt is β or greater. As a result, a may be set to the value of the first reference touch Z RH1, based on the graph of FIG. 7A. However, the value of the first reference touch Z RH1 is not limited to a and may vary depending on types of a semiconductor chip and PCB.

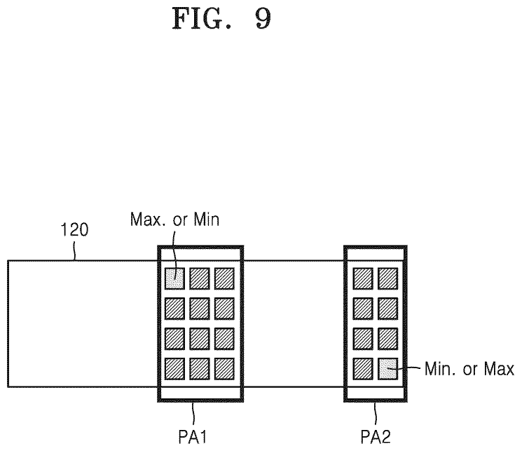

FIG. 8 is a flowchart showing in detail the inspecting of the tilt abnormality of the substrate stage in the substrate stage inspection method of FIG. 1, and FIG. 9 is a conceptual diagram for describing the inspecting of the tilt abnormality of the substrate stage of FIG. 8. FIGS. 8 and 9 will be described with reference to FIG. 1 together, and details that have been already described with reference to FIGS. 1 to 7B will be briefly described or omitted.

Referring to FIGS. 8 and 9, in operation S150 of inspecting the tilt abnormality of the substrate stage 110 in the substrate stage inspection method of various example embodiments, the points of the work area of the first nozzle 140N are selected, in operation S152. As shown in FIG. 9, the work area of the first nozzle 140N may include, for example, the first work area PA1 and the second work area PA2. Also, the first work area PA1 may include 12 points and the second work area PA2 may include 8 points.

A point where the particle Pt is detected is excluded in operation S154 from the selected points, during operation S140 of detecting the particle Pt. By calculating the tilt of the substrate stage 110 by only using normal points excluding the point where the particle Pt is present as such, the tilt abnormality of the substrate stage 110 may be further accurately determined.

Also, an outlier value is removed from the selected points, in operation S156. The removing of the outlier value may also contribute to accurately determining the tilt abnormality of the substrate stage 110.

Next, the tilt abnormality of the substrate stage 110 is determined by comparing a touch Z difference between a point having a maximum touch Z value and a point having a minimum touch Z value, from among the remaining selected points, with the second reference touch Z RH2, in operation S158. For example, in FIG. 9, a top left point (Max. or Min.) of the first work area PA1 may have the maximum touch Z value and a bottom right point (Min. or Max.) of the second work area PA2 may have the minimum touch Z value. Alternatively, touch Z values may be the other way around.

The second reference touch Z RH2 may be set considering various factors. For example, the second reference touch Z RH2 may be set by adding an entire distribution (root sum square (RSS)) to the tilt management standard of the substrate stage 110. Here, factors of the entire distribution may include the thickness distribution of the semiconductor chip 130, the thickness distribution of the solder ball 122, the thickness distribution of the PCB 120, and the error distribution of the measurer. In detail, for example, in the substrate stage inspection method of various example embodiments, the tilt management standard of the substrate stage 110 may be about 10 μm, the thickness distribution of the semiconductor chip 130 may be about ±1.5 um, the thickness distribution of the solder ball 122 may be about ±1.5 μm, the thickness distribution of the PCB 120 may be about ±4 μm, and the error distribution of the measurer may be about ±0.5 um. Accordingly, 10+(1.5²+1.5²+4²+0.5²)^{1/2}=14.56 (μm) may be set as the second reference touch Z RH2. However, the second reference touch Z RH2 is not limited to the above numerical value. For example, types of factors and distributions of the factors included in the entire distribution may vary according to types of a semiconductor chip and PCB, and thus, the second reference touch Z RH2 may vary.

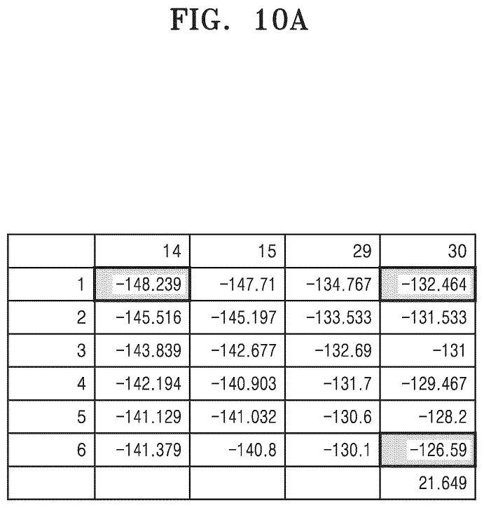

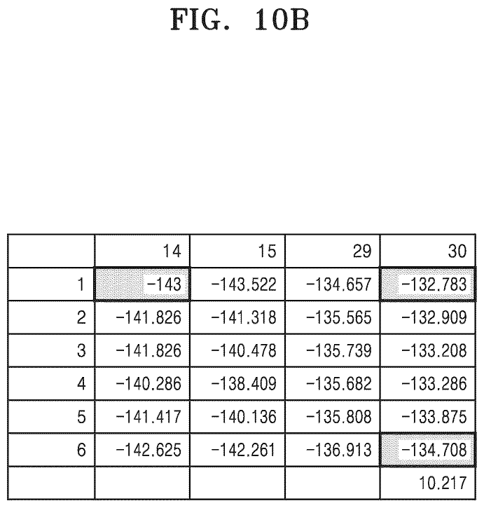

FIGS. 10A and 10B are tables showing touch Z values of points of the PCB 120, which are adjusted by detecting the tilt abnormality of the substrate stage 110 through the calculating of the tilt of the substrate stage 110 to the inspecting of the tilt abnormality in the substrate stage inspection method of FIG. 1. FIG. 10A illustrates the touch Z values of the points of the PCB 120, before the tilt of the substrate stage 110 is adjusted, and FIG. 10B illustrates the touch Z values of the points of the PCB 120, after the tilt of the substrate stage 110 is adjusted.

Referring to FIGS. 10A and 10B, in FIG. 10A, before the tilt is adjusted, at the (14, 1) point of the PCB 120 on the substrate stage 110, the touch Z value is 148.239 that is the maximum, and at a (30, 6) point, the touch Z value is 126.59 that is the minimum, wherein a difference thereof is 21.649 exceeding the second reference touch Z RH2. For reference (−) denotes a direction and may be ignored during size comparison. Thus, it is determined that there is the tilt abnormality in the substrate stage 110 and the tilt of the substrate stage 110 may be adjusted. In FIG. 10B, after the tilt is adjusted, at the (14, 1) point of the PCB 120 on the substrate stage 110, the touch Z value is 143 that is the maximum, and at a (30, 1) point, the touch Z value is 132.783 that is the minimum, wherein a difference thereof is 10.217 that is smaller than the second reference touch Z RH2. Accordingly, the tilt of the substrate stage 110 may be determined to be normal.

FIG. 11 is a flowchart of a substrate stage inspection method together with a substrate stage control process, according to some example embodiments. FIG. 11 will be described with reference to FIG. 1 together, and details that have been already described with reference to FIGS. 1 to 10B will be briefly described or omitted.

Referring to FIG. 11, in the substrate stage inspection method of various example embodiments, 1 is input to n, in operation S201. Here, an integer equal to or greater than 1 may be input to n.

Three points (or at least three points) are selected from a work area of an nth nozzle, in operation S210. For example, because 1 is input to n, the nth nozzle may be a first nozzle. The selecting of the three points has been described above with reference to FIG. 5A.

Then, a plane equation is calculated by using the three points, in operation S220. The calculating of the plane equation has been described above with reference to FIG. 5D.

Data is corrected such that an effect of a tilt of the substrate stage 110 is removed, in operation S230. In relation to the correcting of the data, a method of correcting the data by using the plane equation has been described above with reference to FIGS. 5A to 5E.

Then, it is determined whether the nth nozzle is an alternative nozzle, in operation S240. When the nth nozzle is the alternative nozzle (YES), a nozzle deviation is corrected in operation S245. The correcting of the nozzle deviation may be performed by reflecting an average touch Z value of the alternative nozzle.

When the nth nozzle is not the alternative nozzle (NO), the particle Pt on the substrate stage 110 is detected in operation S250. The detecting of the particle Pt on the substrate stage 110 has been described above with reference to FIGS. 6A to 7B. When the particle Pt is detected (YES), equipment is controlled and an alarm is sounded, in operation S255. The controlling of equipment may include, for example, removing of the particle Pt on the substrate stage 110, washing of a top surface of the substrate stage 110, or the like. Operation S255 of controlling the equipment and sounding the alarm is not limited to the sounding the alarm and may include any operation of notifying a user.

When the particle Pt is not detected (NO), a tilt abnormality of the substrate stage 110 is inspected, in operation S260. The inspecting of the tilt abnormality of the substrate stage 110 has been described above with reference to FIGS. 8 to 10B. When it is determined that there is the tilt abnormality in the substrate stage 110 (YES), the equipment is controlled and the alarm is sounded, in operation S255. Here, the controlling of the equipment may include, for example, adjusting of the tilt of the substrate stage 110. Operation S265 of controlling the equipment and sounding the alarm is also not limited to the sounding the alarm and may include any operation of notifying the user.

When it is determined that there is no tilt abnormality in the substrate stage 110 (NO), it is determined whether operations S210 to S260 have been performed for all combinations of the three points. The all combinations of the three points have been described above with reference to FIG. 5E. When it is determined that operations S210 to S260 have not been performed for all combinations of the three points (NO), operations S210 of selecting the three points to operation S260 of inspecting the tilt abnormality are repeated until operations S210 to S260 are performed for the all combinations.

When operations S210 to S260 have been performed for all combinations of the three points (YES), it is determined whether operations S210 to S260 have been performed for all nozzles, in operation S280. When operations S210 to S260 have not been performed for all nozzles (NO), n+1 is input to n in operation S285. For example, when n is 1 before operation S285 of inputting n+1 to n, n may be 2 after operation S295 is performed. Then, operation S210 of selecting the three points to operation S270 of determining whether operations S210 to S260 have been performed on all combinations of the three points are repeated.

When operations S210 to S260 have been performed for all nozzles (YES), the substrate stage inspection method of various example embodiments is ended.

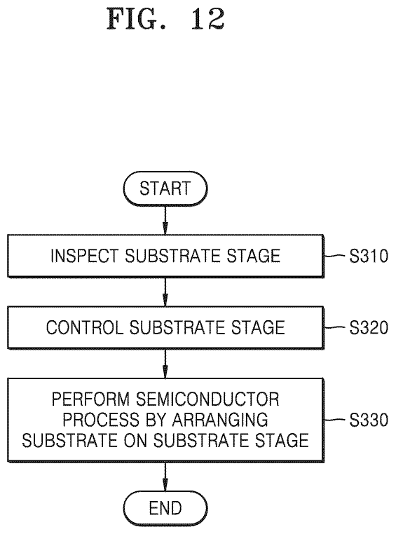

FIG. 12 is a flowchart of a semiconductor device manufacturing method including a substrate stage inspection method, according to some example embodiments. FIG. 12 will be described with reference to FIGS. 1 and 11 together, and details that have been already described with reference to FIGS. 1 to 11 will be briefly described or omitted.

Referring to FIG. 12, according to a semiconductor device manufacturing method including the substrate stage inspection method of various example embodiments, first, the substrate stage 110 is inspected, in operation S310. In the semiconductor device manufacturing method of various example embodiments, operation S310 of inspecting the substrate stage 110 may include the substrate stage inspection method of FIG. 1. Accordingly, operation S310 of inspecting the substrate stage 110 may include operation S110 of receiving the data from the DB to operation S150 of inspecting the tilt abnormality of the substrate stage 110.

After the substrate stage 110 is inspected, the substrate stage 110 is controlled according to a result of the inspection, in operation S320. The controlling of the substrate stage 110 may vary according to operation S140 of detecting the particle Pt and operation S150 of inspecting the tilt abnormality described above. For example, operation S320 of controlling the substrate stage 110 may include operations S255 and S265 of controlling the equipment and sounding the alarm, in the substrate stage inspection method of FIG. 11. Accordingly, when the particle Pt is detected in operation S140 of detecting the particle, the particle Pt may be removed from the substrate stage 110 or the top surface of the substrate stage 110 may be washed in operation S320 of controlling the substrate stage 110. When it is determined that there is the tilt abnormality in operation S150 of inspecting the tilt abnormality, the tilt of the substrate stage 110 may be adjusted in operation S320 of controlling the substrate stage 110.

After the substrate stage 110 is controlled, a substrate may be arranged on the substrate stage 110 and a semiconductor process may be performed, in operation S330. For example, the PCB 120 may be arranged on the substrate stage 110 and a flip-chip bonding process may be performed.

Hereinabove, inventive concepts have been described with reference to various example embodiments shown in the drawings, but embodiments described are only examples and it would be understood by one of ordinary skill in the art that various modifications and equivalent embodiments are possible. Accordingly, the scope of inventive concepts will be defined by the appended claims. Example embodiments are not necessarily mutually exclusive. For example, some example embodiments may include one or more features described with reference to one or more figures and may also include one or mosre other features described with reference to one or more other figures.

What is claimed is:

1. A substrate stage inspection and control method comprising:
receiving data from a database;
calculating a tilt of a substrate stage by using the data;
adjusting the data such that an effect of the tilt is reduced;
detecting a particle on the substrate stage, based on the adjusted data; and
inspecting tilt abnormality of the substrate stage.

2. The substrate stage inspection and control method of claim 1, wherein
the data includes data about a bonding process of bonding a semiconductor chip on a printed circuit board (PCB),
the PCB is placed on the substrate stage, and
the calculating of the tilt comprises,
selecting at least three points from a work area of a first nozzle from among nozzles of a bond head; and
calculating a plane equation by using the at least three points.

3. The substrate stage inspection and control method of claim 2, wherein
the three points are selected from at least two work areas, wherein, in response to there being one work area of the first nozzle, the at least three points are selected from a work area of an alternative nozzle adjacent to the first nozzle, and
the calculating of the tilt to the inspecting of the tilt abnormality are repeated by a number of possible combinations of the three points in the work area.

4. The substrate stage inspection and control method of claim 2, wherein the adjusting of the data comprises adjusting an initial touch height of a location to be corrected to a first touch height, by using the plane equation.

5. The substrate stage inspection and control method of claim 4, wherein, in response to the plane equation being calculated by using an alternative nozzle, the first touch height is adjusted to a second touch height obtained by subtracting an average tough height of the alternative nozzle from the first touch height.

6. The substrate stage inspection and control method of claim 4, wherein the detecting of the particle on the substrate stage comprises determining whether the particle is present on the substrate stage by comparing the first touch height with a set first reference touch height.

7. The substrate stage inspection and control method of claim 6, wherein the first reference touch height is set to a height where a bonding defect does not occur by comparing and evaluating the bonding defect for each location and size of the particle on the PCB.

8. The substrate stage inspection and control method of claim 6, wherein the inspecting of the tilt abnormality comprises:
selecting the work area of the first nozzle;
removing a point where a particle is detected from points in the work area; and
determining a significance of tilt abnormality of the substrate stage by comparing a height difference between a first point and a second point, the first point based on a maximum touch height and the second point based on a minimum touch height from among the points of the work area with a set second reference touch height.

9. The substrate stage inspection and control method of claim 8, wherein the second reference touch height is set based on at least one of a tilt management standard of the substrate stage, a thickness distribution of the semiconductor chip, a thickness distribution of a solder ball, a thickness distribution of the PCB, and an error distribution of a measurer.

10. The substrate stage inspection and control method of claim 1, wherein the calculating of the tilt to the detecting of the tilt abnormality is repeated for each of nozzles of a bond head.

11. A substrate stage inspection and control method comprising:
receiving data about a bonding process of bonding a semiconductor chip on a printed circuit board (PCB);
calculating a plane equation for a substrate stage where the PCB is placed, by using at least three points of a work area of a first nozzle from among all nozzles of a bond head;
correcting an initial touch height of a location to be corrected to a first touch height, by using the plane equation;
determining whether a particle is present on the substrate stage by comparing the first touch height with a set first reference touch height;
inspecting tilt abnormality of the substrate stage by using the work area of the first nozzle; and
determining whether the calculating of the plane equation to the inspecting of the tilt abnormality have been performed for the all nozzles,
wherein, upon determining that the calculating of the plane equation to the inspecting of the tilt abnormality has not been performed for the all nozzles, the calculating of the plane equation to the inspecting of the tilt abnormality is repeated for a nozzle for which the calculating of the plane equation to the inspecting of the tilt abnormality are not performed.

12. The substrate stage inspection and control method of claim 11, further comprising, after the inspecting of the tilt abnormality of the substrate stage:
determining whether the calculating of the plane equation to the inspecting of the tilt abnormality has been performed for all combinations of the at least three points,
wherein, upon determining that the calculating of the plane equation to the inspecting of the tilt abnormality has not been performed for the all combinations, the calculating of the plane equation to the inspecting of the tilt abnormality is repeated for a combination for which the calculating of the plane equation to the inspecting of the tilt abnormality is not performed.

13. The substrate stage inspection and control method of claim 11, further comprising, in response to there being one work area of the first nozzle:
selecting the at least three points from a work area of an alternative nozzle adjacent to the first nozzle.

14. The substrate stage inspection and control method of claim 11, wherein the correcting of the initial touch height comprises, in response to the plane equation being calculated by using an alternative nozzle:
adjusting the first touch height to a second touch height obtained by subtracting an average tough height of the alternative nozzle from the first touch height.

15. The substrate stage inspection and control method of claim 11, wherein the inspecting of the tilt abnormality comprises:
selecting the work area of the first nozzle;
removing a point where a particle is detected from points in the work area; and
determining whether there is the tilt abnormality of the substrate stage by comparing a height difference between a first point and a second point, the first point based on a maximum touch height and the second point based on a a minimum touch height from among the points of the work area with a set second reference touch height.

16. A semiconductor device manufacturing method comprising:
inspecting a substrate stage;
controlling the substrate stage according to a result of the inspecting; and
performing a semiconductor process by arranging a substrate on the substrate stage, wherein the inspecting of the substrate stage comprises,
receiving data about the semiconductor process from a database (DB),
calculating a tilt of the substrate stage by using the data,
adjusting the data such that an effect of the tilt is reduced,
detecting a particle on the substrate stage, based on the adjusted data, and
inspecting tilt abnormality of the substrate stage.

17. The semiconductor device manufacturing method of claim 16, wherein the semiconductor process comprises a bonding process of bonding a semiconductor chip on a printed circuit board (PCB),
the PCB is placed on the substrate stage, as the substrate,
the calculating of the tilt comprises:
selecting at least three points from a work area of one nozzle from among nozzles of a bond head; and
calculating a plane equation by using the at least three points,
wherein the at least three points are selected from at least two work areas,
in response to there being one work area of the one nozzle, the at least three points are selected from a work area of an alternative nozzle adjacent to the one nozzle, and
the calculating of the tilt to the inspecting of the tilt abnormality is repeated by a number of possible combinations of the three points in the work area.

18. The semiconductor device manufacturing method of claim 17, wherein the adjusting of the data comprises:
adjusting an initial touch height of a location to be corrected to a first touch height, by using the plane equation, wherein,
in response to the plane equation calculated by using the alternative nozzle, the first touch height is adjusted to a second touch height obtained by subtracting an average tough height of the alternative nozzle from the first touch height.

19. The semiconductor device manufacturing method of claim 18, wherein
the detecting of the particle on the substrate stage comprises determining whether the particle is present on the substrate stage by comparing the first touch height or the second touch height with a set first reference touch height, and
the first reference touch height is set to a height where a bonding defect does not occur by comparing and evaluating the bonding defect for each location and size of the particle on the PCB.

20. The semiconductor device manufacturing method of claim 19, wherein the inspecting of the tilt abnormality comprises:
selecting the work area of the one nozzle;
removing a point where a particle is detected from points in the work area; and
determining whether there is the tilt abnormality of the substrate stage by comparing a height difference between a first point and a second point, the first point based on a maximum height and the second point based on a minimum height from among the points of the work area with a set second reference touch height.
